(19) United States
(12) Patent Application Publication
(10) Pub. No.: US 2003/0101388 A1
(43) Pub. Date: May 29, 2003

(54) System and method for avoiding waiting repair analysis for semiconductor testing equipment

(75) Inventors: Yuan-Ping Tseng, Hsinchu (TW); Vincent Wang, Hsinchu (TW); Linck Cheng, Taichung (TW); An-Hong Liu, Tainan (TW)

Correspondence Address: DOUGHERTY & TROXELL, SUITE 1404, 5205 LEESBURG PIKE, FALLS CHURCH, VA, 22041, US

(73) Assignee: ChipMOS TECHNOLOGIES INC.

(21) Appl. No.: 09/994,707

(22) Filed: Nov. 28, 2001

(51) Int. Cl. G11C 29/00

(52) U.S. Cl. 714/710

(57) ABSTRACT

A system and a method for avoiding waiting repair analysis for a semiconductor testing equipment are disclosed. The semiconductor testing equipment directly executes next functional test after transferring previous test data regardless of if repair analysis is completed or not. A repair analysis apparatus has a pre-analysis storage device with a larger capacity than the test storage device of the semiconductor testing equipment for off-line repair analysis, so that the semiconductor test is efficiently improved.

### FIELD OF THE INVENTION

The present invention is relating to memory repair analysis (MRA), particularly to a system and a method for avoiding waiting repair analysis for a semiconductor testing equipment, wherein the semiconductor testing equipment is configured to test semiconductor memory devices with redundant circuits.

### BACKGROUND OF THE INVENTION

Conventionally, memories such as dynamic random access memory (DRAM), static random access memory (SRAM), flash memory, double data rate DRAM (DDR DRAM), or system-of-chip (SOC) including memory cells are made by semiconductor manufacturing processes. For example, a plurality of DRAM memory dies (the number is from hundreds to few thousands) are made from a wafer with integrated circuits, such as a wafer of 6 inches, 8 inches, or 12 inches. However, according to small-sized and complicated trends of electronic elements and advanced manufacturing technique, memory capacity is synchronously increased, such as familiar DRAM of 4 Mb or 16 Mb has been increased up to DRAM of 64 Mb, 128 Mb or 256 Mb, even DDR DRAM.

When memory capacity becomes bigger and bigger, it is inevitable that the possibility of generating fail memory cells in semiconductor manufacture becomes higher. Yield of known good dies on a wafer would decrease as the number of fail memory devices increases. Therefore, memory devices have not only a memory region of normal circuit rows and columns, but also a redundant circuit (or called redundant cells). The fail memory cells in the normal region are replaced by redundancy cells by means of the technique of laser repair to change electric circuit paths for enhancing product yield.

For the semiconductor manufacturing process of memories, the technique of memory repair analysis (MRA) has to be adopted between testing and repairing (laser or high voltage melting) operations. The MRA process is performed in order to repair memory cells properly, includes: taking the information of fail cells , and counting of fail cells by testing analyzing and identifying if the fail cells are repairable or not, and how to replace if they are repairable prior to next repairing process.

U.S. Pat. No. 5,841,783 entitled “Fail address analysis and repair system for semiconductor test” has disclosed a memory repair analysis system. As shown in FIG. 1, the system comprises a semiconductor testing equipment 150, a repair address analysis apparatus 160, and a testing equipment control unit 170. Testing equipment control unit 170 serves as a control interface between semiconductor testing equipment 150 and repair address analysis apparatus 160. Semiconductor testing equipment 150 includes a fail memory 151 for storing fail bits information of a memory device, and a control unit 152 for controlling fail memory 151. Repair address analysis apparatus 160 includes a fail buffer memory 161 for storing the information transferred from fail memory 151 to repair address analysis apparatus 160, a fail count unit 162 for analyzing the information in fail buffer memory 161 to be repair information, and a control unit 163 for controlling fail buffer memory 161 and fail count unit 162.

In the familiar memory repair analysis system mentioned above, when a fail bit is identified in a memory device by semiconductor testing equipment 150, the data of a fail bit will be stored into fail memory 151 by control unit 152. Then, before proceeding next functional test by semiconductor testing equipment 150, the data stored in fail memory 151 must be transferred and stored into fail buffer memory 161 of repair address analysis apparatus 160. However, with the complicated trend, bigger and bigger capacity for memory devices, a memory device is requested to be executed for multiple or complicated functional tests. It is necessary to complete the long time memory repair analysis (MRA) (the larger memory capacity, the longer time for repair analysis) before the data of fail bit mentioned above are transferred from fail memory 151 of semiconductor testing equipment 150 into fail buffer memory 161 of repair address analysis apparatus 160 in each time of functional test. So that semiconductor testing equipment 150 must wait for repair address analysis apparatus 160 to complete analysis before transferring data. That is so called “on-line repair analysis”. However, this kind of testing process is too slow. In fact, it is a waste of time for waiting executing several memory repair analysis (MRA) processes, so that it is not efficient and economic for very expensive testing and repair analysis facilities.

As shown in FIG. 2, in the familiar process of on-line test and repair analysis for semiconductor memory, a first testing time which semiconductor testing equipment executes the first functional test from start testing 10 to completion is represented with a drawing number 11. A first repair analyzing time which repair address analysis apparatus executes the first repair analysis operations after first testing is represented with a drawing number 21. With the complicated trend of memory, first repair analyzing time 21 is longer than first testing time 11. When semiconductor testing equipment completes a second functional test 12, repair address analysis apparatus has not completed first repair analysis operation yet, which spent time as indicated by first repair analyzing time 21. Thus, the semiconductor testing equipment must wait for repair address analysis apparatus to complete operation so that a waiting idle time 24 happens. Similarly, there is also an idle time 24 before the third functional test 13 and before the fourth functional test 14 to wait for completing previous repair analysis (second repair analyzing time 22 and third repair analyzing time 23). So that it causes a disadvantageous idleness and a low testing efficiency for very expensive semiconductor testing equipment.

### SUMMARY

It is a main object of the present invention to provide a method for avoiding waiting repair analysis for the semiconductor testing equipment. By means of a distribution circuit, test data obtained after each functional test are directly transferred into at least a repair analysis apparatus for off-line repair analysis. The semiconductor testing equipment may continuously test memories without waiting for repair analysis in order to enhance testing efficiency.

It is another object of the present invention to provide a system for memory test and repair analysis. An individual repair analysis apparatus has an analysis storage device with a bigger capacity than test storage device of the semiconductor testing equipment for off-line repair analysis. So that semiconductor testing equipment can continuously test without waiting repair analysis for improving the test efficiency.

In accordance with the present invention, the method for avoiding waiting repair analysis for semiconductor testing equipment is provided. The semiconductor testing equipment execute a functional test, then a test data are obtained after each functional test. The test data are directly transferred into at least a repair analysis apparatus after each functional tests. The semiconductor testing equipment directly executes next functional test after transferring the test data, wherein repair analysis apparatus has a data capacity bigger than that of semiconductor testing equipment for off-line repair analysis.

### DESCRIPTION OF THE DRAWINGS

FIG. 1 is a block diagram showing a memory test and repair analysis system disclosed in U.S. Pat. No. 5,841,783 “fail address analysis and repair system for semiconductor test”.

FIG. 2 is a diagrammatic view illustrating the spending time in the familiar test and repair analysis processes.

FIG. 3 is a block diagram showing a memory test and repair analysis system in accordance with an embodiment of the present invention.

FIG. 4 is a diagrammatic view illustrating the time spent in the test and repair analysis processes in accordance with an embodiment of the present invention.

FIG. 5 is a diagrammatic view illustrating the time spent in the test and repair analysis processes in accordance with another embodiment of the present invention.

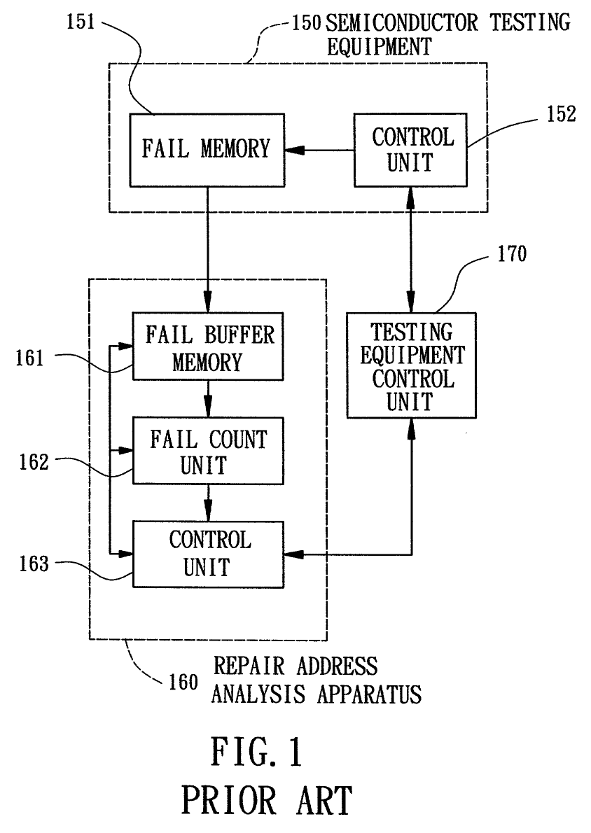

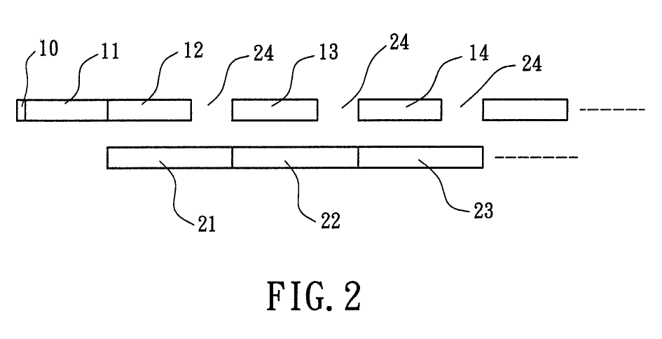

### DETAILED DESCRIPTION OF THE PRESENT INVENTION

Referring to the drawings attached, the present invention will be described by means of the embodiments below.

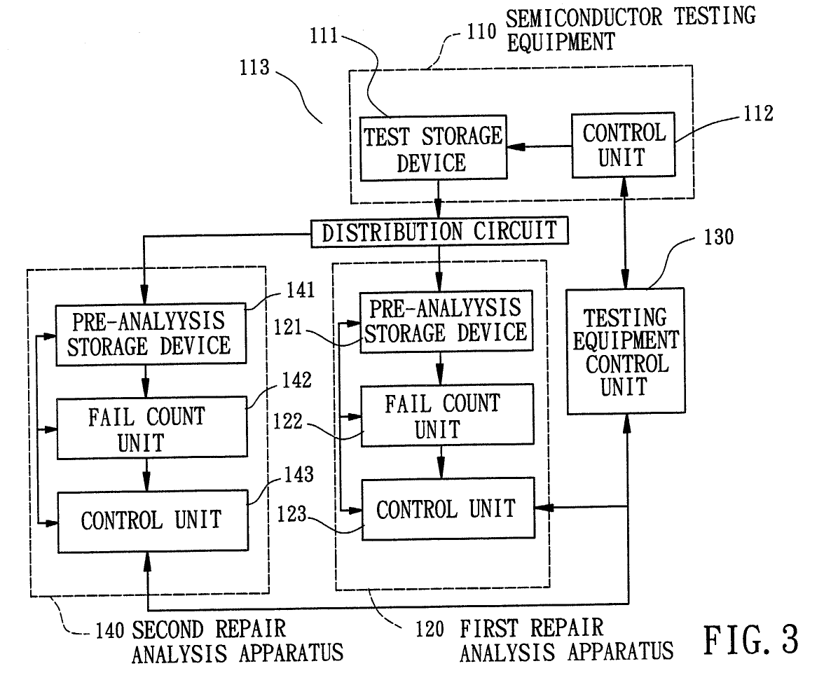

As shown in FIG. 3, the memory test and repair analysis system according to the present invention comprises a semiconductor testing equipment 110, at least a repair analysis apparatus 120, and a testing equipment control unit 130. In this embodiment, there are two repair analysis apparatuses: the first repair analysis apparatus 120 and the second repair analysis apparatus140. Testing equipment control unit 130 becomes the control interface between semiconductor testing equipment 110 and the first repair analysis apparatus 120, and between semiconductor testing equipment 110 and the second repair analysis apparatus 140. Semiconductor testing equipment 110 is used for testing one kind of semiconductor memory device such as dynamic random access memory (DRAM), static random access memory (SRAM), flash memory, double data rate DRAM (DDR DRAM), rambus DRAM or system-on-chip (SOC) with memory. Semiconductor testing equipment 110 includes a test workstation (not shown in the drawings) that has a test head mounting a probe card to contact semiconductor memories on a wafer, a test storage device 111 for storing test data including identified fail bits data such as cache memory, and a control unit 112 for controlling the test storage device 111.

The first repair analysis apparatus 120 comprises a pre-analysis storage device 121, a fail count unit 122, and a control unit 123. Pre-analysis storage device 121 is used to store the test data transferred from test storage device 111 to the first repair analysis apparatus 120 , such as hard disc, magnetic tape driver, or other recording equipment, etc for off-line repair analysis. Generally, the capacity of pre-analysis storage device 121 is much larger than the capacity of test storage device 111. The fail count unit 122 is installed in order to analyze the test data stored in the pre-analysis storage device 121 for determining if memory is repairable and translating into a useful data file about how to repair the repairable memory by redundancy circuit. Control unit 123 serves for controlling pre-analysis storage device 121 and fail count unit 122. In some cases, the first repair analysis apparatus 120 is an individual equipment separated from semiconductor testing equipment 110. Besides, the second repair analysis apparatus 140 as same as the first repair analysis apparatus 120 comprises a pre-analysis storage device 141, a fail count unit 142, and a control unit 143. Similarly, the capacity of pre-analysis storage device 141 is much larger than the capacity of test storage device 111. It is better that the semiconductor testing equipment 110 has a distribution circuit 113 for connecting to pre-analysis storage devices 121 and 141 in order to distribute and transfer the test data.

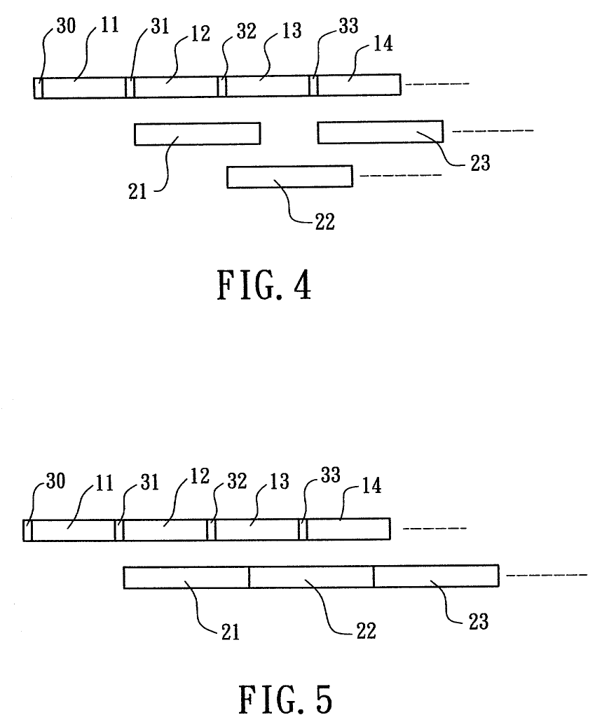

While a plurality of memories such as DRAM of 64 Mb, 128 Mb or 256 Mb on a wafer is requested to test with the memory repair analysis system mentioned above. In the first embodiment, the semiconductor testing equipment 110 connects with the first repair analysis apparatus 120 and the second repair analysis apparatus 140. As shown in FIG. 4, the first test 11 is executed after start testing 30, then obtained first test data stored in the test storage device 111 are transferred into pre-analysis storage device 121 of the first repair analysis apparatus 120 through distribution circuit 113 after the first test 11. The first transferring time 31 is much shorter than the first testing time 11. Then, semiconductor testing equipment 110 directly will execute the second test 12. Thereafter, the second test data of test storage device 111 are transferred into pre-analysis storage device 141 of the second repair analysis apparatus 140 (the second transferring time 32) through distribution circuit 113 for executing the second repair analysis 22, regardless of that if the first repair analysis 21 (previous repair analysis) is completed or not. Semiconductor testing equipment 110 may directly execute the third test 13, the third transferring 33, and the fourth test 14, etc without waiting for the first, the second, and the third repair analysis 21, 22, and 23 because simultaneously a plurality of repair analysis apparatuses 120, 140 share the functional tests data of a semiconductor testing equipment 110 by means of distribution circuit 113. So that it is avoided for semiconductor testing equipment 110 to wait repair analysis, and repair analysis are completed almost synchronously.

Moreover, according to another embodiment of the present invention, the semiconductor testing equipment 110 connects with only a repair analysis apparatus 120 for off-line repair analysis. As shown in FIG. 5, the first test 11 is executed after starting test 30. Then, the first test data stored in test storage device 111 are transferred into pre-analysis storage device 121 of repair analysis apparatus 120. Thereafter, the semiconductor testing equipment 110 directly executes the second test 12 after transferring the first test data. Next, because the capacity of pre-analysis storage device 121 is much larger than the capacity of test storage device 111, the second test data stored in test storage device 111 are transferred into pre-analysis storage device 121 of repair analysis apparatus 120 (the second transmission 32) regardless of that if the first repair analysis 21 (previous repair analysis) is completed or not. Meantime, the semiconductor testing equipment 110 may directly execute the third test 13, the third transmission 33, and the fourth test 14, etc without waiting for the completions of the first, the second, and the third repair analysis 21, 22, and 23. However, repair analysis apparatus 120 executes the first, the second, and the third repair analysis 21, 22, and 23 by off-line operation for avoiding waiting repair analysis for the semiconductor testing equipment.

The above description of embodiments of this invention is intended to be illustrative and not limiting. Other embodiments of this invention will be obvious to those skilled in the art in view of the above disclosure.

What is claimed is:

1. A method for avoiding waiting repair analysis for a semiconductor testing equipment, the semiconductor testing equipment is used for testing semiconductor memories which have redundancy circuits, the method comprising the steps of:
using the semiconductor testing equipment to execute a functional test of a semiconductor memory for obtaining test data after each functional test;
directly transferring the test data to at least a repair analysis apparatus after each functional test, wherein the repair analysis has a pre-analysis storage device with a predetermined capacity for storing the test data; and
directly executing next functional test after transferring the test data regardless of the test data are analyzed or not..

2. The method for avoiding waiting repair analysis for the semiconductor testing equipment in accordance with claim 1, wherein the transferred test data are fail bits addresses for directly transferring to the repair analysis apparatus.

3. The method for avoiding waiting repair analysis for the semiconductor testing equipment in accordance with claim 1, wherein the step of “directly transferring” includes distributing the test data to a plurality of repair analysis apparatuses.

4. A system for performing memory test and repair analysis comprising:
a semiconductor testing equipment including a test storage device for storing test data of memory;
at least a repair analysis apparatus including a pre-analysis storage device for storing the test data transferred from the test storage device of the semiconductor testing equipment; and
a testing equipment control unit used for becoming the control interface between the semiconductor testing equipment and the repair analysis apparatus regardless of repair analysis in the repair analysis apparatus.

5. The system for performing memory test and repair analysis in accordance with claim 4 including a plurality of repair analysis apparatuses.

6. The system for performing memory test and repair analysis in accordance with claim 5, further comprising a distribution circuit for distributing test data to the plurality of repair analysis apparatuses.

7. The system for performing memory test and repair analysis in accordance with claim 4, wherein the capacity of the pre-analysis storage device is larger than the capacity of the test storage device.
